(19) United States
(12) Patent Application Publication
(10) Pub. No.: US 2008/0035196 A1
(43) Pub. Date: Feb. 14, 2008

(54) Method and Apparatus for Preventing Distortion of a Framed Solar Module

(75) Inventors: Paul A. Monus, Frederick, MD (US); George J. Kelly, Mount Airy, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP CORPORATION NORTH AMERICA INC., Warrenville, IL (US)

(21) Appl. No.: 11/576,698

(22) PCT Filed: Oct. 11, 2005
(86) PCT No.: PCT/US05/36771

§ 371 Date: Apr. 5, 2007

Related U.S. Application Data
(60) Provisional application No. 60/619,341, filed on Oct. 15, 2004.

(51) Int. Cl. H01L 31/048

(52) U.S. Cl. 136/251

(57) ABSTRACT

Method and apparatus for preventing the distortion of a frame of a solar module (10) wherein the frame (12) is comprised of two side rails (15) joined together by end members to form a rectangular frame. At least one support bar member (26) is attached to and extends between the rails at a point intermediate their ends. The support bar is of a shape and material capable of withstanding both the compression and the tension forces applied on the frame.

This patent application claims the benefit of U.S. Provisional Patent Application 60/619,341, filed on Oct. 15, 2004.

### FIELD OF THE INVENTION

The present invention relates to method and apparatus for preventing distortion of a framed solar module and in one of its aspects relates to method and apparatus which includes a support bar which can be initially installed or retrofitted into an existing framed solar module to prevent the frame of the solar module from deforming under various loads.

### BACKGROUND OF THE INVENTION

In recent years, considerable advances have been made in using photovoltaic cells or the like to directly convert solar energy into useful electrical energy. Typically, a plurality of photovoltaic cells are encased between a transparent sheet (e.g. glass, plastic, etc.) and a transparent or opaque backsheet, to form flat, rectangular-shaped modules (sometimes also called “laminates or panels”) of a manageable size (e.g. 2½×5′). These modules or laminates are typically held in a frame that surrounds the perimeter of the module. The frame helps protect the module from flexing and it can be used to mount the module. Such framed modules are then shipped to a site where they are assembled into an array onto the roof of a building or the like where the array will be exposed to the sun.

In prior solar array installations, it is typical to secure the frames of the modules onto roof attachment systems (i.e. standoffs) that, in turn, are secured to a roof of a building. For such modules to endure over time, they must withstand all uplift, down forces, and the lateral loads (both compression and tension), that will be imposed on the modules during their operational life. It is many times convenient to mount the framed modules on a roof or other structure by attaching only the ends of the module frame to spaced supports (e.g. rails) on the roof or other structure instead of attaching the frame to roof supports or rails positioned at a location or locations between the ends of the frames. Unfortunately, however, the frames of many of known, typical framed modules often prove inadequate, especially in withstanding the lateral loads on the module during severe conditions and especially when only the ends of the frames are secured to the mounting supports.

For example, in some environments, large snow and ice accumulation on the surface of the laminate of a framed solar module will cause the frame to distort to an extent which can seriously damage the module, itself. Likewise, strong wind currents or other environmental factors can cause the frame to bow or otherwise distort, again causing severe damage to the module. Accordingly, for a framed solar module to successfully function over a prolonged life in such environments, the frames of these solar modules must be strong and stable enough to withstand the more severe loads typically encountered in these environments.

Unfortunately, there are a large number of existing framed solar modules that have already been installed wherein only the end of the frames have been secured to mounting structures. In many areas where severe weather conditions exist, this can cause distortion of the frames of the modules and hence, destruction of the modules, themselves. To be certain that this will not happen, these framed modules would have to be replaced with modules having frames adequate to withstand the damaging loads. This obviously would be very expensive and time consuming and in many cases would be prohibitive for most users.

Accordingly, a need exists for framed solar modules having more stable frames which are resistive to distortion under severe conditions and a need exits for modifying the frames of existing solar modules to prevent distortion thereof, particularly where such modules are installed by attaching only the ends of the frame to the mounting supports.

### SUMMARY OF THE INVENTION

The present invention provides a method and apparatus for preventing the distortion of the frame of a framed solar module even under most severe weather conditions. An important element in the present invention is a support bar element that can be installed in the frame at time of the fabrication of the framed module or can be installed as a “retrofit” after the framed solar module has been in use.

More specifically, the present invention relates to a framed solar module having a frame which, in turn, comprises two side rails joined together by end members to form a rectangular frame. Typical, prior art frames of this type have a tendency to distort when subjected to substantial compression and/or tension loads, e.g. loads caused by the weight of accumulated ice and snow on the laminate within the frame, especially when the frame is mounted by the ends of the frame. In accordance with the present invention, at least one support bar element is attached between the side rails at a point intermediate the ends of the rails. The support bar element is comprised of a bar having a shape and being comprised of material which is capable of withstanding both the compression and the tension forces encountered by the frame during its use.

In a preferred embodiment, the support bar element is comprised of a bar of a length sufficient to span between the side rails of the frame. The preferred bar has a U-shaped cross-section and is comprised of a material (e.g. galvanized steel) which is capable of withstanding both the compression and tension forces applied on the frame. The bar has a tip on each end by which the bar element is attached to the frame. Each tip includes a plate, which is perpendicular to the longitudinal axis of the bar and has a tab at its upper and lower ends thereof.

These tabs are adapted to be positioned within respective passages (e.g. screw bosses) which, in turn, run along the inner length of the side rails to thereby secure the support bar element within the frame. Again, these support bar elements can be installed in the frame initially at the time of fabrication or can be added later as a retrofit for existing frames.

### BRIEF DESCRIPTION OF THE DRAWINGS

The actual construction operation, and apparent advantages of the present invention will be better understood by referring to the drawings, not necessarily to scale, in which like numerals identify like parts and in which:

FIG. 1 is a perspective view of a typical framed solar module installed on a roof of a structure;

FIG. 2 is a cross-sectional view of an embodiment of the framed solar module of present invention;

FIG. 3 is a perspective view of a section of a side rail of the frame of the solar module of FIG. 2;

FIG. 4 is a sectional view of the frame of the solar module of FIG. 2 taken along line 4-4 of FIG. 3;

FIG. 5 is a side view, partly in section, of an embodiment of the support bar of the present invention;

FIG. 6 is an end view of the support bar of FIG. 5 when viewed from line 6-6 of FIG. 5, and

FIG. 7 is an end view of another embodiment of the support bar of FIG. 5.

While the invention will be described in connection with its preferred embodiments, it will be understood that this invention is not limited thereto. On the contrary, the invention is intended to cover all alternatives, modifications, and equivalents that may be included within the spirit and scope of the invention, as defined by the appended claims.

### DETAILED DESCRIPTION OF THE INVENTION

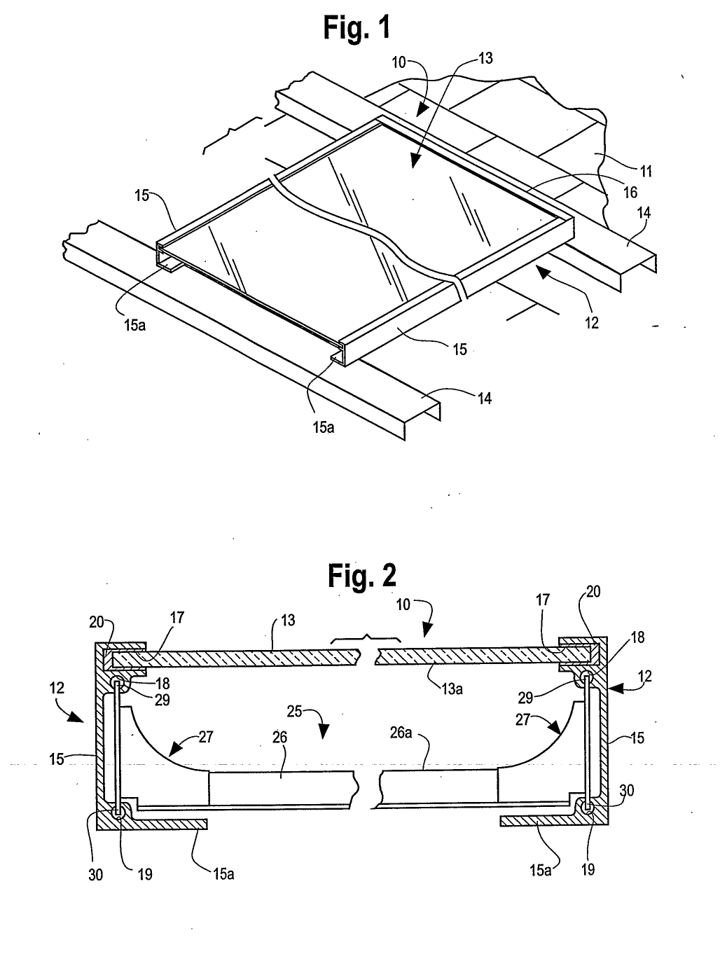

Referring now to the drawings, FIG. 1 illustrates a typical, framed solar module 10 which has been mounted on a roof 11 in accordance with known installation techniques. As will be understood in the art, framed module 10 is typically formed by positioning a plurality of photovoltaic cells (not shown) between a sheet of a transparent material (e.g. glass, plastic, etc.) and an appropriate backing material within a frame 12, whereby the finished framed module is effectively a flat, plate-like PV laminate 13 supported in frame 12. Frame 12 can be affixed directly to the roof or as illustrated, frame 12 of framed module 10 may be positioned on and secured to mounting structures (i.e. pans, “stand-offs”, or roof rails 14 or the like) by bolts, clips, etc. (not shown). As shown in FIG. 1, the framed module can be attached to the mounting structure by affixing only the ends of the frame to the mounting structure 14. The framed module 10 is positioned so that the photovoltaic cells therein will be exposed to the sun for converting its solar energy directly into electricity as will be understood in the art. Only one such mounted framed module is shown in FIG. 1. However, it is to be understood that a plurality of framed modules can be mounted to form, for example, an array of mounted framed modules on a roof or other structure.

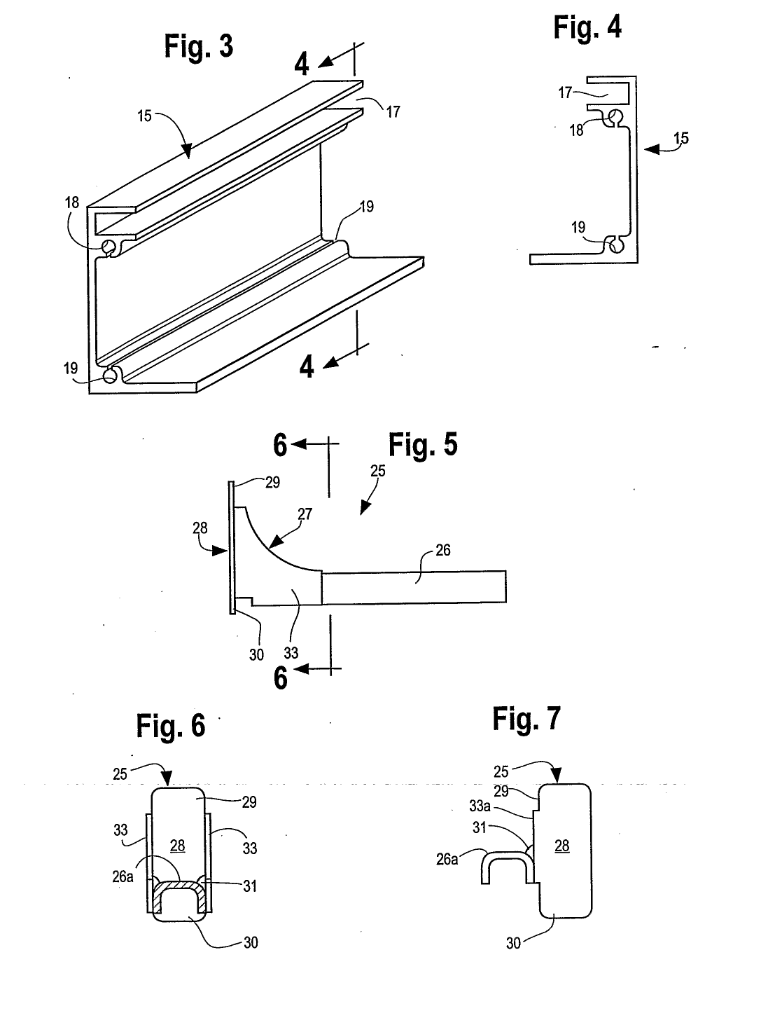

Frame 12, as illustrated, is basically a frame which is well known and is one which is used in the construction of several commercially available framed solar modules in current widespread use. As shown in FIGS. 1-4, frame 12 is comprised of two side rails 15 joined together at both ends by end members 16 (only one shown in FIG. 1 with the other being removed for clarity) to form, in this case, a rectangular frame. Other frame shapes, such as square shaped frames, can be used. Each side rail 15 is typically a mirror image of the other so only one will be described in detail. Side rail 15, which is a length (e.g. 4-5 feet) of a suitable material (e.g. aluminum). Each rail 15 has a channel 17 running along its upper side and an inward, mounting flange 15a for mounting the frame on a roof. Each side rail also has an upper, passage 18, which can be cylindrical as shown, running longitudinally along the length of rail 15 just below channel 17 and a lower, passage 19, which can be cylindrical as shown, running longitudinally along the lower edge of rail 15. End members 16 are typically made of the same stock as the stock used to make the side rails 15. Therefore, end members 16 typically have the same channel, flange and passages as in side rails 15.

As best seen in FIG. 2, the plate-like PV laminate 13, having the photovoltaic cells therein, is positioned in channels 17, respectively, of the two side rails 15 and are secured therein by a substance 20 (e.g. hot butyl or butyl tape). Members 16 are secured at their respective ends to rails 15 by screws, bolts, or like means for fastening (not shown) which, in turn, thread or otherwise pass through the end member and into the respective passages 18 and 19 of side rails 15. When end members 16 are made of the same or similar stock material as side rails 15, the ends of the laminate can be and preferably are fitted into the channel of end members 16 and are typically secured using a substance such as hot butyl or butyl tape. Although only a relatively short portion of each of passages 18,19 is required for the respective screws or other means for fastening, side rails 15 (for example, aluminum channel material) are routinely manufactured with passages 18, 19 (commonly known as “screw bosses” in the industry) extending along the entire length of the rails.

When framed modules 10, such as described above, are installed on roofs or the like, many times the frame 12 is attached only at or near its ends (see FIG. 1) thereby leaving the frame 12 with relatively reduced support across its length. In some environments, this does not pose a problem. However, in environments where severe weather conditions may occur (e.g. snow, ice, wind, etc.), a frame unsupported along its length can lead to early failure of the framed module 10. As will be readily recognized, such failure seriously detracts from the use of solar modules in these areas, and, prior to this invention, it was time consuming and expensive to correct framed solar modules that were already installed under such conditions.

For example, in frigid areas, snow and/or ice may accumulate on the surface of module 10 and the weight thereof can cause severe distortion of the frame which, in turn, can lead to damage or destruction of the module, itself. It has been found that the unsupported side rails 15 of the frame on a typical end-mounted, framed solar module tend to warp under the load and instead of the rails remaining substantially vertical, they lean outwards, sometimes up to a 45° angle of deflection. This weakens the frame and allows pressures and stresses to build up on the glass surface of the module, eventually causing the glass to break under the weight of the snow/ice. This finding was surprising since other approaches, including the use of significantly stronger frames have failed to produce modules that can withstand these loads in end-mounted, framed modules.

In accordance with the present invention, one or more support bar elements are provided at points along the lengths of the side rails 15 (e.g. midpoint between their ends). These support bars span across the framed module from one side rail 15 to the other. The support bar element not only provides tensional strength to the frame to keep the side rails from bowing outward but also preferably provides compressional strength to keep the rails from bowing inward. Also, the bar element helps prevent the rails from warping inwards or outwards from vertical. These support bar elements may be added to frame 12 by any conventional means, e.g. bolts, screws, welding, adhesives, etc. but preferably are attached in a manner described below.

Basically support bar element 25 (FIGS. 2, 5, and 6) is comprised of a bar 26 having a length sufficient to span between rails 15 of frame 12 and is of a suitable material which is capable of resisting both compression and tension forces, such as compression and tension forces applied to the ends of the support bar element in the same direction as the longitudinal axis of the support bar element. Examples of such materials are aluminum and its alloys, stainless steel, or preferably galvanized steel. Bar 26 may take various cross-sectional configurations (e.g. round, rectangular, triangular, etc.) and may be solid or hollow and may have a cross-sectional shape such a “U” or a “V”. Preferably, as shown, bar 26 is formed with a U-shaped cross-section where the bottom of the U is relatively flat instead of curved (FIG. 6). Such a configuration provides the necessary strength while being lighter and less expensive to manufacture than would be a solid bar.

A means for attaching the bar element 25 to frame 12 (e.g. tip 27) is positioned at both ends of bar 26. Each tip 27 has a plate 28 which is perpendicular to the longitudinal axis of the bar. The plate 28 includes an upper tab 29 and a lower tab 30 for a purpose described below. The tips 27 can be formed integral with the bar by extrusion or stamping procedures but due to the expense involved, preferably the tips 27 are formed separately and then affixed to the respective ends of the bar by any appropriate means, e.g. welding 31. As shown, in FIG. 6, preferably bar 26 is effectively centered on plate 28 between two supports 33 which, in turn, are attached to the sides of plate 28 with the proper welds being affected to secure tip 27 on the end of bar 26. Tips 27 (i.e. plate 28 and supports 33) are preferably formed from the same material as is bar 25. Preferably, the U-shaped bar 26 is attached to tips 27 in an inverted position (FIG. 6) for a purpose described below. The embodiment shown in FIG. 7 is effectively the same as that described above except bar 26 is welded to only one support 33a which may be formed integral with plate 28 by bending a single piece of stock.

To assemble bar elements 25 into frame 12, the support bar 26 can first be insulated with an insulation material, e.g. wrapped with an insulative tape, if desired. The bar element 25 is then manipulated to position the tabs 29, 30 on the tips 27 at each end of bar 26 into passages or screw bosses 18, 19, respectively, and the bar element is positioned at its desired location along the side rails 15. The element 25 is preferably positioned so that the inverted or flat surface 26a (FIG. 6) of the U-shaped bar 26 is facing the underside 13a of the plate-like PV laminate 13 (FIG. 2). This is important since the PV laminate 13, even with bars 25 in place, can still sag enough under severe condition to bring it into contact with the bar. If the legs of the U-shaped bar were pointed upward towards the laminate 13, they could pierce or otherwise damage the laminate upon contact. Thus, in an embodiment of this invention, a screw, rivet, bolt, glue or other similar fastening means is not necessary to attach the support bar element to the frame. Such support bar element in accordance with such embodiment of this invention can be attached to the frame side rails simply by the placement of the tabs within the passages in the frame as just described without the use screws, bolts, rivets, glue or other fastening means. In other embodiments, screws, bolts, rivets, glue or other fastening means can be used to attach the support bar element to the frame.

While one support bar element 25 located midway between the ends of rails 15 is usually sufficient to prevent distortion of frame 12 under most conditions, additional bars can be spaced along the frame if deemed necessary. Also, these support bars may be added when the frame is initially fabricated and before installation. As one important feature of the present invention however is the fact that the present invention can be use to easily “retrofit” many of the existing framed solar modules in use today by adding the support bar element of the present invention to framed solar modules even after the modules have been installed.

U.S. Provisional Patent Application 60/619,341, filed on Oct. 15, 2004, is incorporated herein by reference in its entirety.

What is claimed is:

1. A support bar element for preventing distortion of a frame of a solar module, said solar module comprising an underside and said frame comprising two side rails, said support bar comprising:
a bar comprising a U cross-sectional shape, a length sufficient to span between said two side rails, a flat surface, and being comprised of a material capable of withstanding both the compression and the tension forces applied on said frame;
means for affixing said bar to said frame; and
where when installed in a solar module, the flat surface of said bar faces the underside of the module.

2. The support bar of claim 1 comprising steel.

3. A frame for a solar module, said solar module comprising an underside, comprising:
two side rails joined by end members to form a frame; and
at least one support bar comprising a U cross-sectional shaped member spanning between said side rails immediate the ends of said side rails, said support bar member having a flat surface and comprising a material capable of withstanding both the compression and the tension forces applied on said frame, and where the flat surface faces the underside of the module.

4. The support bar of claim 3 wherein the bar comprises steel.

5. A method of preventing distortion of a frame for a solar module wherein said frame is comprised of two side rails joined by end members to form a frame, and wherein said solar module has an underside, said method comprising:
affixing a support bar member having a U cross-sectional shape between said side rails at a point intermediate the ends of said side rails, said support bar member having a flat surface and comprising a material capable of withstanding both the compression and the tension forces applied on said frame; and
where the flat surface faces the underside of the module.

6. The method of claim 5 wherein the support bar comprises steel.

7. A support bar element for preventing distortion of a frame of a solar module, said solar module comprising an underside and said frame comprising two side rails, said support bar comprising:
a bar comprising a length sufficient to span between said two side rails and being shaped and comprised of a material so that it withstands both compression and tension forces applied on said frame; and
means for affixing said bar to said frame.

8. The support bar of claim 7 comprising steel.

9. A frame for a solar module, said solar module comprising an underside, comprising:
two side rails joined by end members to form a frame; and
at least one support bar comprising a material and being shaped so it withstands both compression and tension forces applied on said frame.

10. The support bar of claim 9 wherein the bar comprises steel.

11. A method of preventing distortion of a frame for a solar module wherein said frame is comprised of two side rails joined by end members to form a frame, and wherein said solar module has an underside, said method comprising:
affixing a support bar member between said side rails at a point intermediate the ends of said side rails, said support bar member comprising a material and being shaped so that it withstands both compression and tension forces applied on said frame.

12. The method of claim 11 wherein the support bar comprises steel.
